(19) United States
(12) Patent Application Publication
(10) Pub. No.: US 2024/0186597 A1
(43) Pub. Date: Jun. 6, 2024

(54) DEVICE AND METHOD FOR DISCHARGING BATTERY

(71) Applicant: SK On Co., Ltd., Seoul (KR)

(72) Inventor: Alexander YARBROUGH, Commerce, GA (US)

(21) Appl. No.: 18/072,873

(22) Filed: Dec. 1, 2022

(51) Int. Cl. H01M 10/44; H01M 10/42; H01M 10/48; H02J 7/00

(52) U.S. Cl. CPC H01M 10/448; H01M 10/425; H01M 10/482; H02J 7/0025; H01M 2010/4271; H01M 2220/20

(57) ABSTRACT

A battery discharge device is disclosed. The battery discharge device comprises: a discharge circuit connected to a battery module; a sensor unit configured to measure a state of the battery module, the sensor unit connected to at least one of the discharge circuit or the battery module; and a control unit configured to obtain information on the state of the battery module from the sensor unit, wherein the discharge circuit includes: a terminal unit having a first terminal unit and a second terminal unit, the first and second terminal units being electrically connected to the battery module; and a first electric circuit electrically connected to the first and second terminal units, wherein the control unit is configured to determine whether the battery module operates normally, based on the information on the state of the battery module.

### TECHNICAL FIELD

The present disclosure relates to a device and method for discharging a battery. In particular, the present disclosure relates to a battery discharge device and method for stably discharging a battery.

### BACKGROUND

Battery modules have been used in electric vehicles or energy storage devices. Battery modules that have reached the end of their lifespan or are not delivered as normal products in the production process need to be discarded.

In general, the battery module has power remaining therein. Therefore, when the battery module is cut so as to discard the battery module, there is a risk of fire or electric shock.

In order to discard the battery module, it is necessary to reduce the remaining power of the battery. That is, it is necessary to discharge the battery module so that a voltage of the battery is reduced to a predetermined value or less.
(Patent Document 1) JP 6567014 B2

### SUMMARY

An object of the present disclosure is to address the above-described and other problems.

Another object of the present disclosure is to provide a battery discharge device and method for stably discharging a battery module.

Another object of the present disclosure is to provide a battery discharge device and method for reducing a voltage of a battery module to a first threshold voltage by providing a first electric circuit and reducing the voltage of the battery module to a second threshold voltage by providing a second electric circuit.

Another object of the present disclosure is to provide a battery discharge device and method for selectively connecting a first electric circuit and a second electric circuit to a battery module.

Another object of the present disclosure is to provide a battery discharge device and method for determining whether a battery module operates normally while discharging the battery module.

Another object of the present disclosure is to provide a battery discharge device and method for dividing a plurality of battery cells included in a battery module into a plurality of battery cell groups and determining whether an individual battery cell group operates normally.

In order to achieve the above-described and other objects and needs, in one aspect of the present disclosure, there is provided a method for discharging a battery module, the method comprising: connecting a first electric circuit to the battery module; a first discharging of the battery module until a voltage of the battery module reaches a first threshold voltage; connecting a second electric circuit to the battery module; and a second discharging of the battery module until the voltage of the battery module reaches a second threshold voltage.

In another aspect of the present disclosure, there is provided a battery discharge device comprising: a discharge circuit connected to a battery module; a sensor unit configured to measure a state of the battery module, the sensor unit connected to at least one of the discharge circuit or the battery module; and a control unit configured to obtain information on the state of the battery module from the sensor unit, wherein the discharge circuit includes: a terminal unit having a first terminal unit and a second terminal unit, the first and second terminal units being electrically connected to the battery module; and a first electric circuit electrically connected to the first and second terminal units, wherein the control unit is configured to determine whether the battery module operates normally, based on the information on the state of the battery module.

Effects of the battery discharge device and method according to the present disclosure are described as follows.

According to at least one aspect of the present disclosure, the present disclosure can provide a battery discharge device and method for stably discharging a battery module.

According to at least one aspect of the present disclosure, the present disclosure can provide a battery discharge device and method for reducing a voltage of a battery module to a first threshold voltage using a first electric circuit and reducing the voltage of the battery module to a second threshold voltage using a second electric circuit.

According to at least one aspect of the present disclosure, the present disclosure can provide a battery discharge device and method for selectively connecting a first electric circuit and a second electric circuit to a battery module.

According to at least one aspect of the present disclosure, the present disclosure can provide a battery discharge device and method for determining whether a battery module operates normally while discharging the battery module.

According to at least one aspect of the present disclosure, the present disclosure can provide a battery discharge device and method for dividing a plurality of battery cells included in a battery module into a plurality of battery cell groups and determining whether an individual battery cell group operates normally.

Additional scope of applicability of the present disclosure will become apparent from the detailed description given blow. However, it should be understood that the detailed description and specific examples such as embodiments of the present disclosure are given merely by way of example, since various changes and modifications within the spirit and scope of the present disclosure will become apparent to those skilled in the art from the detailed description.

### BRIEF DESCRIPTION OF THE DRAWINGS

The accompanying drawings, which are included to provide a further understanding of the disclosure and are incorporated in, constitute a part of the disclosure, illustrate embodiments of the disclosure and together with the description and serve to explain the principle of the disclosure.

FIG. 1 is a block diagram of a battery discharge device according to an embodiment of the present disclosure.

FIG. 2 illustrates a battery cell assembly according to an embodiment of the present disclosure.

FIG. 3 illustrates a plurality of battery cells classified into a plurality of battery cell groups.

FIG. 4 illustrates that a plurality of battery cell groups is connected to a plurality of bus bars.

FIG. 5 is a flow chart illustrating a method of discharging a battery according to an embodiment of the present disclosure.

FIG. 6 illustrates a first discharge step according to an embodiment of the present disclosure.

FIG. 7 is a flow chart illustrating a step of determining whether a battery module according to an embodiment of the present disclosure operates normally.

FIG. 8 illustrates that a first electric circuit and a second electric circuit are connected by a switch module in accordance with an embodiment of the present disclosure.

### DETAILED DESCRIPTION

Reference will now be made in detail to embodiments of the disclosure, examples of which are illustrated in the accompanying drawings. Wherever possible, the same reference numbers will be used throughout the drawings to refer to the same or like parts. In general, a suffix such as “module” and “unit” may be used to refer to elements or components. Use of such a suffix herein is merely intended to facilitate description of the present disclosure, and the suffix itself is not intended to give any special meaning or function. It will be noted that a detailed description of known arts will be omitted if it is determined that the detailed description of the known arts can obscure the embodiments of the disclosure. The accompanying drawings are used to help easily understand various technical features and it should be understood that embodiments presented herein are not limited by the accompanying drawings. As such, the present disclosure should be construed to extend to any alterations, equivalents and substitutes in addition to those which are particularly set out in the accompanying drawings.

The terms including an ordinal number such as first, second, etc. may be used to describe various components, but the components are not limited by such terms. The terms are used only for the purpose of distinguishing one component from other components.

When any component is described as “being connected” or “being coupled” to other component, this should be understood to mean that another component may exist between them, although any component may be directly connected or coupled to the other component. In contrast, when any component is described as “being directly connected” or “being directly coupled” to other component, this should be understood to mean that no component exists between them.

A singular expression can include a plural expression as long as it does not have an apparently different meaning in context.

In the present disclosure, terms “include” and “have” should be understood to be intended to designate that illustrated features, numbers, steps, operations, components, parts or combinations thereof are present and not to preclude the existence of one or more different features, numbers, steps, operations, components, parts or combinations thereof, or the possibility of the addition thereof.

In the drawings, sizes of the components may be exaggerated or reduced for convenience of explanation. For example, the size and the thickness of each component illustrated in the drawings are arbitrarily illustrated for convenience of explanation, and thus the present disclosure is not limited thereto unless specified as such.

If any embodiment is implementable differently, a specific order of processes may be performed differently from the order described. For example, two consecutively described processes may be performed substantially at the same time, or performed in the order opposite to the described order.

In the following embodiments, when layers, areas, components, etc. are connected, the following embodiments include both the case where layers, areas, and components are directly connected, and the case where layers, areas, and components are indirectly connected to other layers, areas, and components intervening between them. For example, when layers, areas, components, etc. are electrically connected, the present disclosure includes both the case where layers, areas, and components are directly electrically connected, and the case where layers, areas, and components are indirectly electrically connected to other layers, areas, and components intervening between them.

A battery module may be a secondary battery module. The battery module may be discarded if it is determined to be defective in a production process. The battery module may be in a state of being charged to a certain level in the production process. Thus, before the battery module is discarded and disassembled, the battery module needs to be discharged.

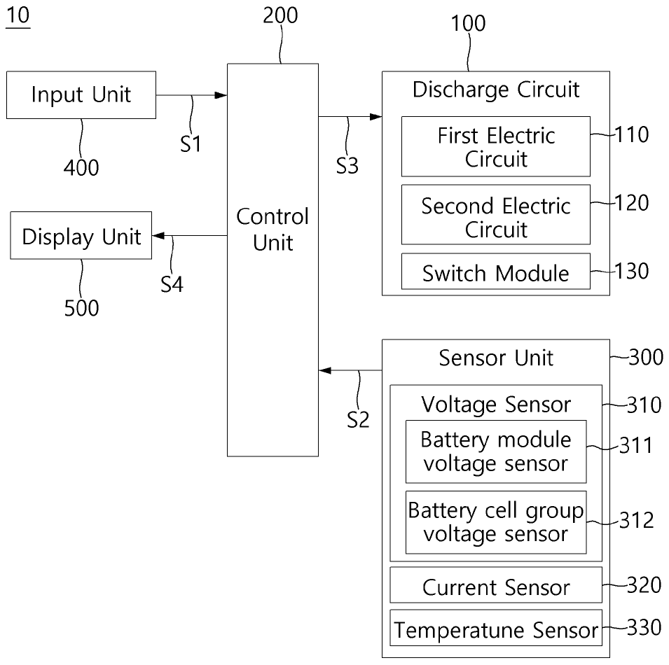

FIG. 1 is a block diagram of a battery discharge device 10 according to an embodiment of the present disclosure. Referring to FIG. 1, the battery discharge device 10 may include a discharge circuit 100. The discharge circuit 100 may be connected to a battery module and may discharge the battery module.

The discharge circuit 100 may include a first electric circuit 110. The first electric circuit 110 may be connected to the battery module to reduce a voltage of the battery module. The discharge circuit 100 may include a second electric circuit 120. After the first electric circuit 110 connected to the battery module is disconnected from the battery module, the second electric circuit 120 may be connected to the battery module to reduce the voltage of the battery module.

The discharge circuit 100 may include a switch module 130. The switch module 130 may connect or disconnect at least one of the first electric circuit 110 and the second electric circuit 120 and the battery module in response to switching. The switch module 130 may connect the first electric circuit 110 and the battery module or connect the second electric circuit 120 and the battery module in response to the switching.

The battery discharge device 10 may include a control unit 200. The control unit 200 may receive and process signals or information. The control unit 200 may generate signals or information. The control unit 200 may be implemented using at least one of a processor, a CPU, a GPU, a computer, a laptop, and a server. The control unit 200 may be connected to the discharge circuit 100. The control unit 200 may control the discharge circuit 100.

The battery discharge device 10 may include a sensor unit 300. The sensor unit 300 may be connected to at least one of the discharge circuit 100 and the battery module. For instance, the sensor unit 300 may be connected to the battery module. The sensor unit 300 may measure a state of the battery module. The sensor unit 300 may be connected to the control unit 200. The sensor unit 300 may be referred to as a “measurement circuit”.

The sensor unit 300 may include a voltage sensor 310. The voltage sensor 310 may include a battery module voltage sensor 311. The battery module voltage sensor 311 may measure the voltage of the battery module. The voltage sensor 310 may include a battery cell group sensor 312. The battery cell group sensor 312 may measure voltages of a plurality of battery cell groups.

The sensor unit 300 may include a current sensor 320. The current sensor 320 may measure a current flowing into and out of the battery module or measure a current flowing through the discharge circuit 100.

The battery discharge device 10 may include an input unit 400. The input unit 400 may receive a signal or information from the outside. For example, the input unit 400 may receive a signal or information from a user. The input unit 400 may be connected to the control unit 200.

The battery discharge device 10 may include a display unit 500. The display unit 500 may display state information of the battery discharge device 10. The display unit 500 may be connected to the control unit 200.

The input unit 400 may generate a first signal S1. The first signal S1 may include command information related to an operation of the battery discharge device 10. The first signal S1 may be transmitted to the control unit 200.

The sensor unit 300 may generate a second signal S2. The second signal S2 may include information on the state of the battery module. The second signal S2 may be transmitted to the control unit 200.

The control unit 200 may generate output signal S3 and S4 based on input signal S1 and S2. The input signal S1 and S2 may include at least one of the first signal S1 and the second signal S2. The output signal S3 and S4 may include at least one of a third signal S3 and a fourth signal S4.

The third signal S3 may be transmitted to the discharge circuit 100. The discharge circuit 100 may operate based on the third signal S3. For example, the switch module 130 may operate based on the third signal S3.

The fourth signal S4 may be transmitted to the display unit 500. The display unit 500 may operate based on the fourth signal S4. For example, the display unit 500 may display the state of the battery module based on the fourth signal S4. For example, the display unit 500 may display the voltage of the battery module or/and the voltage of the battery cell group.

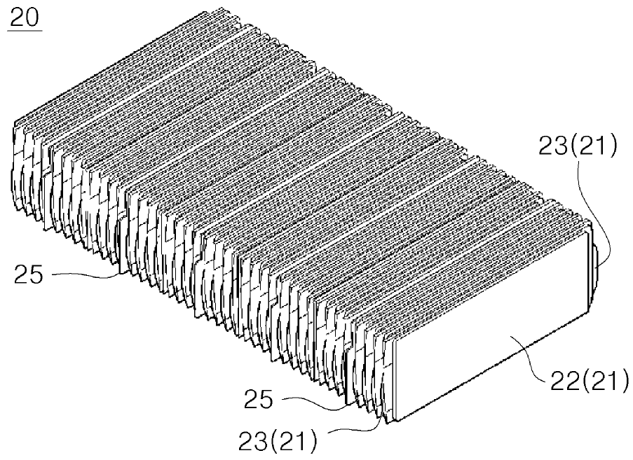

Referring to FIG. 2, the battery module may include a battery cell assembly 20. The battery cell assembly 20 may be accommodated in a battery module case. The battery cell assembly 20 may include a plurality of battery cells 21. The plurality of battery cells 21 may be stacked or disposed in one direction.

The battery cell 21 may include a battery cell body 22 extending from one end to the other end. The battery cell body 22 may include an electrode assembly. The electrode assembly may be surrounded by an exterior material.

The battery cell 21 may include an electrode lead tab 23. The electrode lead tab 23 may protrude from an end of the battery cell body 22. A plurality of electrode lead tabs 23 may be provided. The plurality of electrode lead tabs 23 may respectively protrude from the one end and the other end of the battery cell body 22.

The battery cell assembly 20 may include a pad 25. The pad 25 may be a surface pressure pad. The pad 25 may be disposed between two adjacent battery cells 21. The pad 25 may classify the plurality of battery cells 21 into a plurality of battery cell groups. In other words, the plurality of battery cells 21 may be classified into a plurality of battery cell groups.

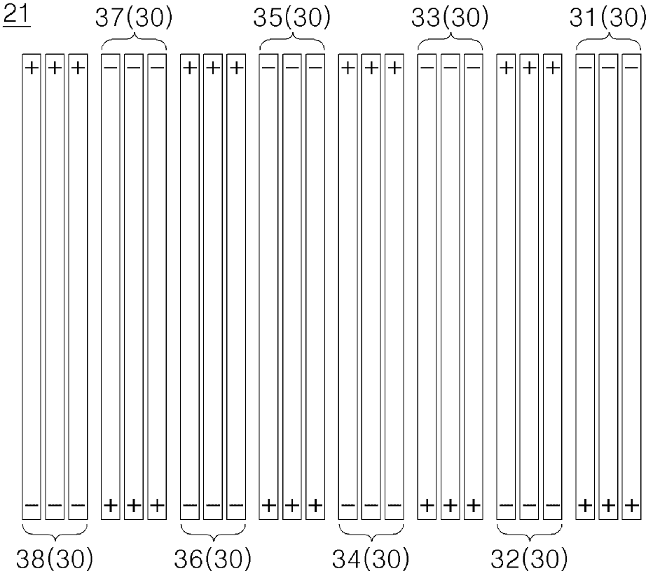

Referring to FIG. 3, a plurality of battery cells 21 may be stacked or disposed in one direction. For convenience of explanation, the battery cell 21 shown in FIG. 3 is schematically indicated and polarity is indicated at the ends of the battery cell 21. Polarity is either positive (+) or negative (−). For example, one of the two electrode lead tabs 23 (refer to FIG. 2) of the battery cell 21 may be a positive (+) and the other may be a negative (−).

The plurality of battery cells 21 may be classified into a plurality of battery cell groups 30. The battery cells 21 belonging to one battery cell group 30 may have the same polarity arrangement. For example, the battery cells 21 belonging to one battery cell group 30 may be connected in parallel.

A plurality of battery cell groups 30 may be provided. For example, the battery cell group 30 includes a first battery cell group 31, a second battery cell group 32, a third battery cell group 33, a fourth battery cell group 34, and a fifth battery cell group 35, a sixth battery cell group 36, a seventh battery cell group 37, and an eighth battery cell group 38. The battery cell groups 30 may be connected in series.

The number of battery cells 21 belonging to each of the plurality of battery cell groups 30 may be the same. For example, three battery cells 21 may form one battery cell group 30.

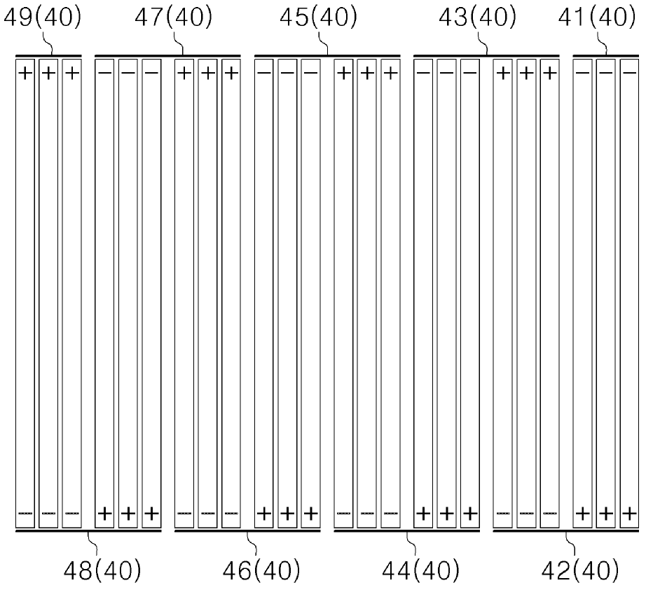

Referring to FIG. 3 and FIG. 4, a plurality of bus bars 40 may be connected to a plurality of battery cells 21. For example, the plurality of bus bars 40 may be connected to the plurality of battery cell groups 30. For example, two bus bars 40 may be respectively connected to both ends of one battery cell group 30. For example, one bus bar 40 may be connected to the positive electrode lead tabs 23 (refer to FIG. 2) of one battery cell group 30, and another bus bar 40 may be connected to the negative electrode lead tabs 23 (refer to FIG. 2) of the one battery cell group 30.

The bus bars 40 may be provided in plural. The number of bus bars 40 may correspond to the number of battery cell groups 30. For example, the number of bus bars 40 may be one more than the number of battery cell groups 30. For example, if the number of battery cell groups 30 is N, the number of bus bars 40 may be N+1.

The bus bar 40 may comprise a first bus bar 41, a second bus bar 42, a third bus bar 43, a fourth bus bar 44, a fifth bus bar 45, a sixth bus bar 46, a seventh bus bar 47, an eighth bus bar 48 and a ninth bus bar 49.

The first bus bar 41 may be connected to one end of the first battery cell group 31. The second bus bar 42 may be connected to the other end of the first battery cell group 31 and one end of the second battery cell group 32. That is, the second bus bar 42 may connect the first battery cell group 31 and the second battery cell group 32 in series.

The third bus bar 43 may be connected to the other end of the second battery cell group 32 and one end of the third battery cell group 33. That is, the third bus bar 43 may connect the second battery cell group 32 and the third battery cell group 33 in series.

The fourth bus bar 44 may be connected to the other end of the third battery cell group 33 and one end of the fourth battery cell group 34. That is, the fourth bus bar 44 may connect the third battery cell group 33 and the fourth battery cell group 34 in series.

The fifth bus bar 45 may be connected to the other end of the fourth battery cell group 34 and one end of the fifth battery cell group 35. That is, the fifth bus bar 45 may connect the fourth battery cell group 34 and the fifth battery cell group 35 in series.

The sixth bus bar 46 may be connected to the other end of the fifth battery cell group 35 and one end of the sixth battery cell group 36. That is, the sixth bus bar 46 may connect the fifth battery cell group 35 and the sixth battery cell group 36 in series.

The seventh bus bar 47 may be connected to the other end of the sixth battery cell group 36 and one end of the seventh battery cell group 37. That is, the seventh bus bar 47 may connect the sixth battery cell group 36 and the seventh battery cell group 37 in series.

The eighth bus bar 48 may be connected to the other end of the seventh battery cell group 37 and one end of the eighth battery cell group 38. That is, the eighth bus bar 48 may connect the seventh battery cell group 37 and the eighth battery cell group 38 in series. The ninth bus bar 49 may be connected to the other end of the eighth battery cell group 38.

The number of battery cell groups 30 may be N. Both ends of the j-th battery cell group may be respectively connected to the j-th bus bar and the j+1-th bus bar. ‘j’ is a natural number and may be 1 or more and N or less. The reference sign of the j-th battery cell group may be 30+j. The reference sign of the j-th bus bar may be 40+j. The reference sign of the j+1th bus bar may be 40+j+1.

The first bus bar 41 may be one of both electrodes of the battery module. The ninth bus bar 49 may be the other one of both electrodes of the battery module. The bus bar 40 may be connected to the discharge circuit 100 (refer to FIG. 1). For example, the first bus bar 41 and the ninth bus bar 49 may be respectively connected to both ends of the discharge circuit 100 (refer to FIG. 1).

The potential of the bus bar 40 may be measured. The potentials of the plurality of bus bars 40 may be measured respectively. For example, the potential of the j-th bus bar may be the j-th potential Pⱼ. The voltage of the battery cell group 30 may be a difference in potential of two bus bars 40 connected to the battery cell group 30. The voltage of the j-th battery cell group may be the j-th voltage Vⱼ. The j-th voltage Vⱼ may be the difference between the j+1th potential Pⱼ₊ᵢ and the j-th potential Pⱼ.

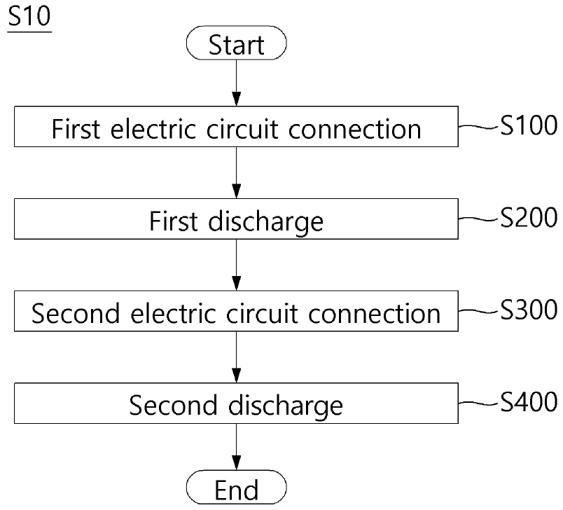

FIG. 5 is a flow chart illustrating a method S10 of discharging a battery according to an embodiment of the present disclosure.

Referring to FIGS. 1 to 5, the battery discharge method S10 according to an embodiment of the present disclosure may comprise a first electric circuit connection step S100. In the step S100, the first electric circuit 110 may be connected to the battery module.

The battery discharge method S10 according to an embodiment of the present disclosure may comprise a first discharge step S200. In the step S200, the battery module may be discharged until a voltage of the battery module is a first threshold voltage. The battery module voltage sensor 311 may measure the voltage of the battery module.

The first threshold voltage may depend on the number of battery cells 21 belonging to the battery cell group 30. For example, when the number of battery cells 21 belonging to one battery cell group 30 is M, the first threshold voltage may be M*1.4[V] to M*1.6[V]. The control unit 200 may be configured to disconnect the first electric circuit 110 from the battery module when the voltage of the battery module is equal to or less than the first threshold voltage.

The battery discharge method S10 according to an embodiment of the present disclosure may comprise a second electric circuit connection step S300. In the step S300, the second electric circuit 120 may be connected to the battery module. Before the step S300, the first electric circuit 110 may be disconnected from the battery module. The control unit 200 may be configured to connect the second electric circuit 120 with the battery module when the voltage of the battery module is equal to or less than the first threshold voltage.

The battery discharge method S10 according to an embodiment of the present disclosure may comprise a second discharge step S400. In the step S400, the battery module may be discharged until the voltage of the battery module is a second threshold voltage. The second threshold voltage may be M*0.17[V] to M*0.25[V]. The control unit 200 may be configured to disconnect the second electric circuit 120 from the battery module when the voltage of the battery module is equal to or less than the second threshold voltage after discharge.

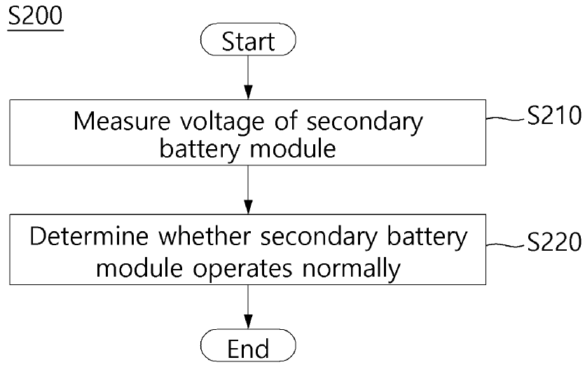

Referring to FIGS. 1 to 6, the battery discharge device 10 may discharge a battery module. The first discharge step S200 may comprise a step S210 of measuring the voltage of the battery module. In the step S210, the voltage of the battery module may be measured. For example, the battery module voltage sensor 311 may measure the voltage of the battery module. In the step S210, the voltages of the battery cell groups 30 may be measured. For example, the battery cell group voltage sensor 312 may measure the voltage of each of the plurality of battery cell groups 30. For example, the second signal S2 may include information on the voltage of the battery module and the voltage of each of the plurality of battery cell groups 30.

The first discharge step S200 may comprise a step S220 of determining whether the battery module operates normally. In the step S220, the control unit 200 may determine, based on the second signal S2, whether each of the plurality of battery cell groups 30 operates normally. In the step S220, the control unit 200 may determine, based on the second signal S2, whether the battery module operates normally.

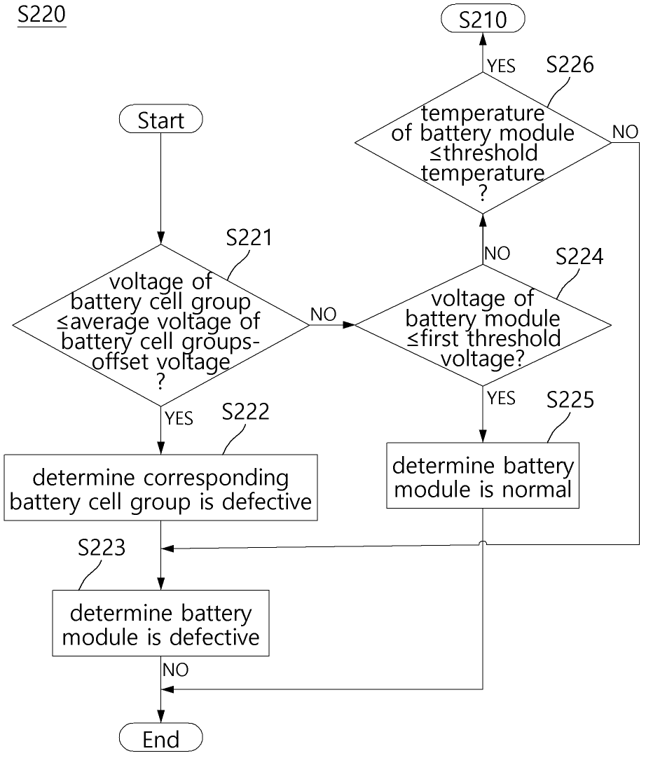

Referring to FIGS. 1 to 7, the step S220 of determining whether the battery module operates normally may include the step S221 of comparing the voltage of each of the plurality of battery cell groups 30 with the average voltage of the plurality of battery cell groups 30. In this step S221, the control unit 200 may calculate an average voltage of the plurality of battery cell groups 30.

In this step S221, the control unit 200 may determine whether the j-th voltage Vⱼ, which is the voltage of the j-th battery cell group 30, is less than or equal to a voltage subtracting the offset voltage from the average voltage of the plurality of battery cell groups 30. The offset voltage, for instance, 0.2[V]. The average voltage of the plurality of battery cell groups 30 may stand for an average value of voltages of battery cell groups 30 excluding the j-th battery cell group among the plurality of battery cell groups 30.

The step S220 of determining whether the battery module operates normally may include a step S222 of determining the corresponding battery cell group 30 is defective. When the j-th voltage Vⱼ, which is the voltage of the j-th battery cell group, is equal to or less than the voltage subtracting the offset voltage from the average voltage of the plurality of battery cell groups 30, the control unit 200 may determine that the j-th battery cell group is defective.

The step S220 of determining whether the battery module operates normally may include a step S223 of determining the battery module is defective. When it is determined that there is a defective battery cell group 30 among the plurality of battery cell groups 30, the control unit 200 may determine that the battery module is defective. When the battery module is defective, it is difficult to discharge the battery module, so the battery module may be processed in a different manner.

The step S220 of determining whether the battery module operates normally may include a step S224 of comparing the voltage of the battery module with the first threshold voltage. When the j-th voltage Vⱼ, which is the voltage of the j-th battery cell group, is higher than the voltage subtracting the offset voltage from the average voltage of the plurality of battery cell groups 30, the control unit 200 may conduct this step S224. In the step S224, the control unit 200 may compare the voltage of the battery module with the first threshold voltage.

The step S220 of determining whether the battery module operates normally may include a step S225 of determining that the battery module is normal. When the voltage of the battery module is equal to or less than the first threshold voltage, the control unit 200 may determine that the battery module is normal, the first discharge step S200 may end.

The step S220 of determining whether the battery module operates normally may include a step S226 of comparing the temperature of the battery module with a threshold temperature. When the voltage of the battery module is higher than the first threshold voltage, the control unit 200 may compare the temperature of the battery module with the threshold temperature. The temperature sensor 330 may measure the temperature of the battery module and provide the control unit 200 with the information on the temperature of the battery module. When the temperature of the battery module is equal to or less than threshold temperature, the control unit 200 may conduct the step S210 of measuring the voltage of the battery module. When the temperature of the battery module is higher than the threshold temperature, the control unit 200 may conduct the step S223 of determining the battery module is defective.

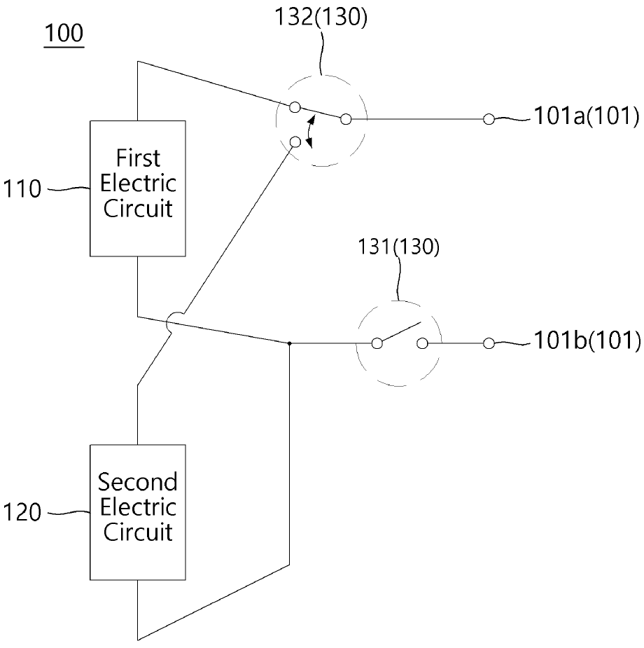

Referring to FIGS. 1 and 8, the discharge circuit 100 may include the first electric circuit 110 the second electric circuit 120. The first electric circuit 110 and the second electric circuit 120 may be connected to each other in parallel. The first electric circuit 110 may include at least one resistor. The second electric circuit 120 may include at least one resistor.

The discharge circuit 100 may include a terminal unit 101. The terminal unit 101 may be connected to a terminal of the battery module. The terminal unit 101 may include a first terminal unit 101a and a second terminal unit 101b. For example, the first terminal unit 101a may be connected to the first bus bar 41 (refer to FIG. 4). For example, the second terminal unit 101b may be connected to the ninth bus bar 49 (refer to FIG. 4).

The discharge circuit 100 may include a switch module 130. The switch module 130 may include an on/off switch 131. The on/off switch 131 may connect the terminal unit 101 to the first electric circuit 110. The on/off switch 131 may connect the terminal unit 101 to the second electric circuit 120. The on/off switch 131 may be connected to the second terminal unit 101b. In response to switching of the on/off switch 131, the electric circuit loop may be open or closed. The electric circuit loop may be a loop that the first electric circuit 110 and the battery module form. The electric circuit loop may be a loop that the second electric circuit 120 and the battery module form.

The switch module 130 may include a changeover switch 132. The changeover switch 132 may be connected to the terminal unit 101. The changeover switch 132 may connect the terminal unit 101 to the first electric circuit 110. The changeover switch 132 may connect the terminal unit 101 to the second electric circuit 120.

In response to switching of the changeover switch 132, the terminal unit 101 and the first electric circuit 110 may be electrically connected, or the terminal unit 101 and the second electric circuit 120 may be electrically connected. For example, the first electric circuit 110 and the second electric circuit 120 may not be electrically connected to the terminal unit 101 at the same time.

In response to switching of the changeover switch 132, the changeover switch 132 may be connected to the first electric circuit 110. In the first electric circuit connection step S100, the changeover switch 132 may be electrically connected to the first electric circuit 110.

When the changeover switch 132 is electrically connected to the first electric circuit 110, the battery module and the first electric circuit 110 may form an electric circuit loop. When the battery module and the first electric circuit 110 form the electric circuit loop, the first discharge step S200 may be conducted.

In response to switching of the changeover switch 132, the changeover switch 132 may be connected to the first electric circuit 110. When the changeover switch 132 is connected to the second electric circuit 120, the changeover switch 132 may be disconnected to the first electric circuit 110. In the first electric circuit connection step S100, the changeover switch 132 may be connected to the first electric circuit 110.

When the changeover switch 132 is electrically connected to the second electric circuit 120, the battery module and the second electric circuit 120 may form an electric circuit loop. When the battery module and the second electric circuit 120 form the electric circuit loop, the second discharge step S400 may be conducted.

Some embodiments or other embodiments of the present disclosure described above are not mutually exclusive or distinct from each other. Configurations or functions of some embodiments or other embodiments of the present disclosure described above can be used together or combined with each other.

It is apparent to those skilled in the art that the present disclosure can be embodied in other specific forms without departing from the spirit and essential features of the present disclosure. Accordingly, the above detailed description should not be construed as limiting in all aspects and should be considered as illustrative. The scope of the present disclosure should be determined by rational interpretation of the appended claims, and all modifications within an equivalent scope of the present disclosure are included in the scope of the present disclosure.

1. A method for discharging a battery module, the method comprising:
connecting a first electric circuit to the battery module;
a first discharging of the battery module until a voltage of the battery module reaches a first threshold voltage;
connecting a second electric circuit to the battery module; and
a second discharging of the battery module until the voltage of the battery module reaches a second threshold voltage.

2. The method of claim 1, wherein the battery module includes a plurality of battery cells classified into a plurality of battery cell groups,
wherein the battery cells belonging to a first battery cell group of the plurality of battery cell groups are connected in parallel, and
wherein the plurality of battery cell groups are connected in series.

3. The method of claim 2, wherein the first threshold voltage is M*1.4[V] to M*1.6[V], where M is a number of the battery cells belonging to the first battery cell group.

4. The method of claim 2, wherein the second threshold voltage is M*0.17[V] to M*0.25l[V], where M is a number of the battery cells belonging to the first battery cell group.

5. The method of claim 2, further comprising:
measuring a voltage of the battery module and a voltage of each of the plurality of battery cell groups; and
comparing the voltage of each of the plurality of battery cell groups with an average voltage of the plurality of battery cell groups to determine whether the battery module operates normally.

6. The method of claim 5, further comprising:
comparing the voltage of each of the plurality of battery cell groups with the average voltage of the plurality of battery cell groups;
determining one battery cell group of the plurality of battery cell groups is defective, when the voltage of the one battery cell group is equal to or less than a voltage level set by subtracting an offset voltage from the average voltage of the plurality of battery cell groups; and
determining the battery module is defective when the one battery cell group is defective.

7. The method of claim 6, further comprising:
comparing the voltage of the battery module with the first threshold voltage, when the voltage of the one battery cell group is higher than the voltage level; and
determining the battery module is normal, when the voltage of the battery module is equal to or less than the first threshold voltage.

8. The method of claim 7, wherein when the battery module is normal, the first discharging is stopped, and the second electric circuit is connected to the battery module.

9. The method of claim 7, further comprising determining that the battery module is operating normally by comparing a temperature of the battery module with a threshold temperature when the voltage of the battery module is higher than the first threshold voltage.

10. The method of claim 9, wherein the voltage of the battery module and the voltage of each of the plurality of battery cell groups are measured when the temperature of the battery module is equal to or less than the threshold temperature, and
wherein the battery module is determined to be defective when the temperature of the battery module is higher than the threshold temperature.

11. A battery discharge device comprising:
a discharge circuit connected to a battery module;
a sensor unit configured to measure a state of the battery module, the sensor unit connected to at least one of the discharge circuit or the battery module; and
a control unit configured to obtain information on the state of the battery module from the sensor unit,
wherein the discharge circuit includes:
a terminal unit having a first terminal unit and a second terminal unit, the first and second terminal units being electrically connected to the battery module; and
a first electric circuit electrically connected to the first and second terminal units,
wherein the control unit is configured to determine whether the battery module operates normally, based on the information on the state of the battery module.

12. The battery discharge device of claim 11, wherein the discharge circuit further includes:
a changeover switch connected to the second terminal unit and the first electric circuit;
a second electric circuit connected to the changeover switch and the second terminal unit, the second electric circuit being connected to the first electric circuit in parallel,
wherein the battery module forms an electric circuit loop with one of the first electric circuit and the second electric circuit in response to switching of the changeover switch.

13. The battery discharge device of claim 12, wherein the control unit is configured to control the changeover switch so as to disconnect the first electric circuit from the battery module and connect the second electric circuit to the battery module when a voltage of the battery module is equal to or less than a first threshold voltage.

14. The battery discharge device of claim 13, wherein the battery module includes a plurality of battery cells classified into a plurality of battery cell groups,
wherein the battery cells belonging to a first battery cell group of the plurality of battery cell group are connected in parallel,
wherein the plurality of battery cell groups are connected in series, and
wherein the first threshold voltage is M*1.4[V] to M*1.6[V], where M is a number of the battery cells belonging to the first battery cell group.

15. The battery discharge device of claim 14, wherein the control unit disconnects the second electric circuit from the battery module when the voltage of the battery module is equal to or less than a second threshold voltage.

16. The battery discharge device of claim 15, wherein the second threshold voltage is M*0.17[V] to M*0.25[V], where M is a number of the battery cells belonging to the first battery cell group.

17. The battery discharge device of claim 15, wherein the discharge circuit includes an on/off switch connected to at least one of the first terminal unit and the second terminal unit, wherein the on/off switch opens or closes the electric circuit loop in response to switching the on/off switch.

18. The battery discharge device of claim 11, wherein the sensor unit includes:
a battery module voltage sensor configured to measure a voltage of the battery module; and
a battery cell group voltage sensor configured to measure a voltage of each of the plurality of battery cell groups.

19. The battery discharge device of claim 11, wherein the battery module includes:
a plurality of battery cells classified into a plurality of battery cell groups; and
a plurality of bus bars electrically connecting the plurality of battery cell groups in series.

20. The battery discharge device of claim 19, wherein the number of the plurality of bus bars is a sum of one and the number of the plurality of battery cell groups.
